(19) United States
(12) Patent Application Publication
(10) Pub. No.: US 2015/0075612 A1
(43) Pub. Date: Mar. 19, 2015

(54) HIGH EFFICIENCY SOLAR MODULE STRUCTURE

(71) Applicant: Changzhou Almaden Co., Ltd., Changzhou (CN)

(72) Inventors: Jinxi LIN, Changzhou (CN); Jinhan LIN, Changzhou (CN); Yuting LIN, Wufeng Township (TW); Chun Liang LIN, New Taipei City (TW)

(21) Appl. No.: 14/490,178

(22) Filed: Sep. 18, 2014

(30) Foreign Application Priority Data
Sep. 18, 2013 (CN) 201310431018.2

(51) Int. Cl. H01L 31/055; H01L 31/048; H01L 31/056

(52) U.S. Cl. CPC H01L 31/055; H01L 31/056; H01L 31/048
USPC 136/257

(57) ABSTRACT

The present invention is related to a solar module structure comprising in sequence a back sheet that can reflect light, a first polymeric layer blended with phosphors, a double-sided photovoltaic cell layer, a second polymeric layer and a cover plate that is made of tempered glass. The solar module of the present invention can significantly increase the photoelectrical conversion efficiency.

### CROSS-REFERENCE TO RELATED APPLICATION

This application claims priority to Chinese patent application number 201310431018.2, filed on Sep. 18, 2013 and the contents of which in its entirety are herein incorporated by reference.

### BACKGROUND OF THE INVENTION

1. Field of the Invention

The present invention relates to a high efficiency solar module, particularly a monocrystalline or polycrystalline silicon solar module.

2. Description of the Related Art

A solar module can absorb light, convert the light energy into electrical energy by photoelectric effect performed in the photovoltaic cell layer therein and thus achieve the purpose of power generation. Recently, photovoltaic materials most commonly used as a photovoltaic cell layer include silicon-based materials such as monocrystalline silicon, polycrystalline silicon, amorphous silicon-based materials, thin-film materials such as cadmium telluride, copper indium selenide, copper indium gallium selenide, gallium arsenide, and organic materials such as photosensitizing dyes. Among these photovoltaic materials, silicon-based materials are the most developed ones; and among the silicon-based solar cells, monocrystalline silicon and polycrystalline silicon solar cells are the most popular ones.

Currently, the photoelectric conversion efficiency of a solar cell, depending on the material used, is about 14% to 20%. In other words, the electrical power generated from an irradiation light of 100 energy units is only 14 to 20 energy units. An important factor why the light energy cannot be completely converted to electrical energy is that the material can absorb energy from the light in a part of the spectrum, and the absorption efficiencies for different wavelengths are not the same (see FIG. 1). For monocrystalline silicon or polycrystalline silicon, the principle absorption wavelength band is from 400 nm to 800 nm. It is found that around 10% of sun light has a wavelength of 300 nm to 400 nm (the range of ultraviolet, blue to sky blue light) (see FIG. 2), but the conversion efficiency of a monocrystalline or polycrystalline solar cell for such wavelength of light is below 50%. If the light in such wavelength can be utilized well, the overall efficiency of a solar cell would be enhanced.

In view of the above, it has been proposed in literatures that phosphors which absorb light in specific wavelength band and convert the wavelength of the light to one that is easier to be absorbed by the photovoltaic cell layer, thereby increasing the overall photoelectric conversion efficiency. For example, in U.S. Pat. No. 8,124,871, it is proposed that a transparent light conversion film can be placed above the outer surface of the silicon solar cell layer, wherein the light conversion film comprises, in addition to a polymer, phosphor powders having the chemical formula of (Sr_{1-X}Ba_{X})(BO₂)₂:EuLiCl (where 0≦x≦1) which can absorb the light having a wavelength of less than 400 nm and re-radiate it in 500 to 780 nm, so that the light can be better absorbed by the silicon cell layer (see FIG. 3, in which 10 represents a silicon wafer, 20 represents the light conversion film and 21 represents a phosphor). However, in this prior art, the phosphors are disposed above the photovoltaic, so most of the converted light will be scattered and advance toward the surface of incidence, and thus, cannot be utilized by the photovoltaic cell layer. In addition, the phosphors in this prior art are blended in an additional light conversion film. This not only increases the time and cost required to process but also causes defects due to mismatch between layers or poor adhesion.

The present invention provides a new structure of a solar cell module for improving the photoelectric conversion efficiency of overall solar cells without the above problems.

### SUMMARY OF THE INVENTION

The objective of the present invention is to provide a solar module structure comprising in sequence:

a solar backsheet that can reflect light;

a first polymeric layer comprising phosphors;

a double-sided photovoltaic cell layer;

a second polymeric layer;

a cover plate made of tempered glass.

The solar module structure according to the present invention has the following features and advantages:

(1) The backsheet of the solar cell module structure of the present invention can reflect light, and the photovoltaic cell layer used is double-sided. By using the two components, the light passing the photovoltaic cell layer but not being absorbed, or the light passing through the gaps between the cells, can be reused, so the overall photoelectric conversion efficiency can be enhanced.

(2) The solar cell module structure of the present invention has a polymeric layer blended with phosphors and placed beneath the photovoltaic cell layer (i.e., the other side of the light-incident surface). The phosphors within the polymeric layer can convert sunlight having short wavelength into light of longer wavelength that is easier to be absorbed by the photovoltaic cell layer, and since conversion of light is performed between the backsheet and the photovoltaic cell layer, the problem in the aforementioned prior art, that is, the light will directly leave from the light-incident surface by scattering, can be solved.

(3) The preferred phosphor used in the solar cell module structure according to the present invention has peak absorbance of 300 nm to 400 nm and peak emission of 450 nm to 500 nm. This is the optimal range for monocrystalline and polycrystalline silicons, and the overall conversion efficiency can be significantly enhanced.

### BRIEF DESCRIPTION OF THE DRAWINGS

FIG. 1 shows the conversion efficiency of a polycrystalline silicon.

FIG. 2 is the spectrum of sunlight (AM 1.5 G).

FIG. 3 is an embodiment of the transparent light conversion film of prior art.

FIG. 4 is one embodiment of the solar module structure according to the present invention.

FIG. 5 is another embodiment of the solar module structure according to the present invention.

FIG. 6 shows the absorption spectrum of the phosphors of Examples 1 and 2 (SPS and FPF).

FIG. 7 shows the emission spectrum of the phosphors of Examples 1 and 2 (SPS and FPF).

FIG. 8 shows the absorption spectrum of the phosphors of Comparative examples 1 and 2 (SAS and FAF).

FIG. 9 shows the emission spectrum of the phosphors of Comparative examples 1 and 2 (SAS and FAF).

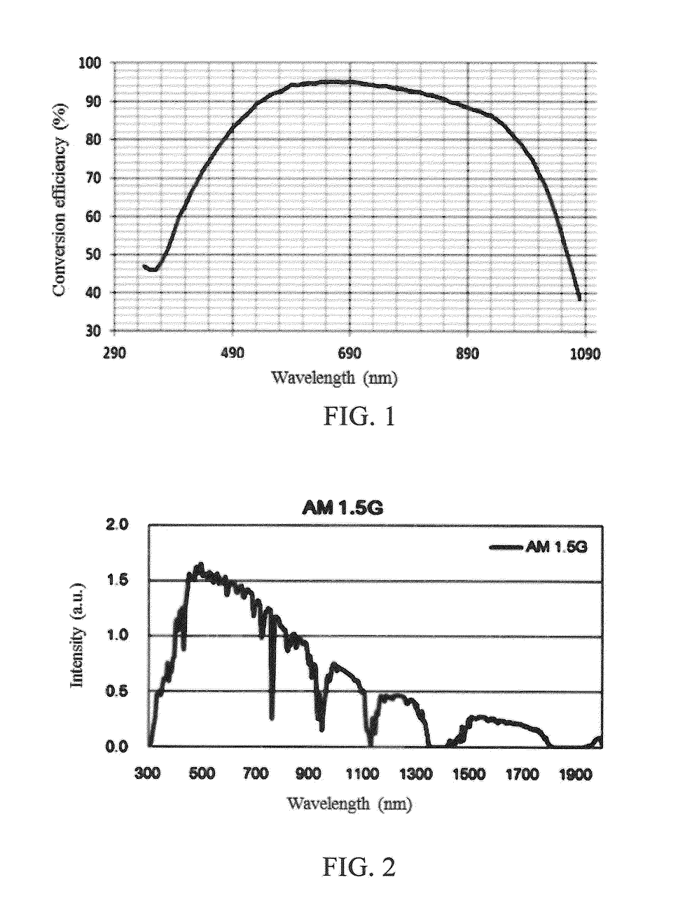

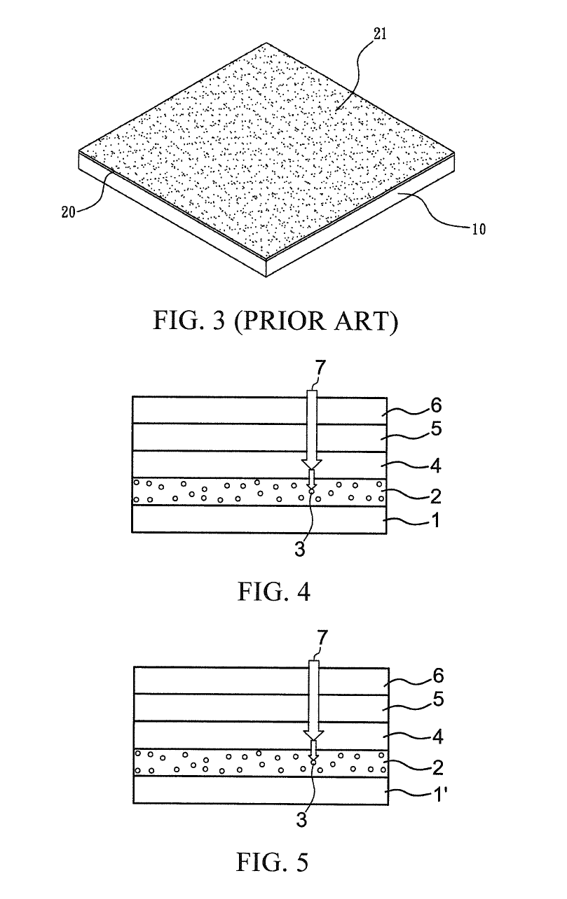

### DETAILED DESCRIPTION OF THE PRESENT INVENTION

In this context, unless otherwise indicated, a singular term (such as “a”) also includes a plural form thereof. In this context, all embodiments and exemplary terms (for example, “such as”) only aim at making the present invention more prominent, but are not intended to limit the scope of the present invention; terms in this specification should not be construed as implying that any component not claimed may form a necessary component for implementing the present invention.

One of the objectives of the present invention is to provide a solar module structure comprising in sequence:

a solar backsheet that can reflect light;

a first polymeric layer comprising phosphors;

a double-sided photovoltaic cell layer;

a second polymeric layer;

a cover plate made of tempered glass,

wherein the phosphors have peak absorbance of 300 nm to 400 nm and peak emission of 450 nm to 500 nm.

Schematic views of the solar module structure of the present invention are shown in FIGS. 4 and 5.

The structure shown in FIG. 4 comprises glass 1 which is coated with a light-reflecting material, a first polymeric layer 2 in which phosphors 3 are blended, a double-sided photovoltaic cell layer 4, a second polymeric layer 5 and a cover plate 6 made of tempered glass. A portion of light 7 which is entered from the cover plate is absorbed by the photovoltaic cell layer 4 and converted into electrical energy, while the remaining portion (mainly having wavelength of 300 nm to 400 nm) passes the photovoltaic cell layer 4, enters the first polymeric layer 2, is converted into light of longer wavelength by phosphors 3, return to the photovoltaic cell layer 4 via scattering or reflection and then is converted into electrical energy.

The structure shown in FIG. 5 is similar to that in FIG. 4, but the light-reflecting glass 1 is replaced by white backsheet 1′.

The features and manufacturing of each layer of the solar module structure of the present invention are further explained as follows.

### Solar Backsheet

To protect the internal components and prolong the lifetime of the solar module, the solar backsheet should have good physical strength to compression, tension and bending as well as good weatherability against water, moisture, oxidation and thermal deformation. The solar backsheet according to the present invention can be made of conventional materials for a backsheet, such as a multi-layered structure of polyvinyl fluoride (PVF)/adhesive layer/polyethylene terephthalate (PET)/adhesive layer/PVF, PVF/adhesive layer/PET, PET/adhesive layer/SiO₂ PET, and coating layer/PET/adhesive layer/ethylene vinyl acetate (EVA) resin prime layer.

To effectively reflect light, an additional metal layer, such as aluminum foil or silver foil can be adhered to the backsheet when one of the aforementioned multi-layered structures is used. Alternatively, white substance such as TiO₂, BaSO₄ and Teflon can be added to one or more layers thereof, so that the light can be reflected from the backsheet and reused by the photovoltaic cell layer.

Glass also can be used as the solar backsheet in the present invention. To meet the requirements as stated above, the glass substrate used in the solar module structure of the present invention should have the following properties: compressive strength of at least about 120 MPa, bending strength of at least about 120 MPa, and tensile strength of at least 90 MPa. Preferably, the glass substrate used in the solar module structure of the present invention should have compressive strength ranging from about 120 MPa to about 300 MPa, bending strength ranging from about 120 MPa to about 300 MPa and tensile strength ranging from about 90 MPa to about 180 MPa. Normal glass does not have the requisite mechanical properties, so tempered glass is required.

A conventional physically tempered glass might have sufficient mechanical properties, but must normally be over 3 millimeters thick to avoid deformation. The thickness not only increases the cost for material and transportation cost but also decreases heat dissipation of the solar module. A conventional chemically tempered glass might achieve the aforementioned mechanical properties and is not subject to the limitations imposed on thickness by machining. However, chemically tempered glass degrades very easily due to environmental factors, and has certain other disadvantages that limit its range of application, such as being difficult to coat, stripping easily and being costly.

In a preferred embodiment of the present invention, a novel type of physically tempered glass prepared by aerodynamic heating and cooling procedures is used as the solar backsheet. The terminology “aerodynamic heating” refers to a process of transferring heat to an object by using air/gas floatation to replace conventional rolling transport in a heating furnace or tempering furnace. For a more detailed preparation of the physically tempered glass, reference may be made to the content in the application of Chinese Patent Application No. 201110198526.1 (also US Patent Publication No. 2013/0008500 A1). When such physically tempered glass is applied, the thickness of the solar backsheet can be reduced to no more than 2 mm while sufficient physical properties are still provided.

A glass solar backsheet is advantageous over a polymeric solar backsheet, because when a glass is used as the solar backsheet, metals (such as silver, aluminum, gold, chromium and an alloy thereof) for light reflection can be directly deposited on the backsheet by means such as physical vapor deposition, so adhesives can be omitted. By doing so, preparation of the backsheet would contain fewer process steps; and more importantly, the problems caused by adhesives can be avoided, so the reliability can be increased. Deposition of the metal layer on the glass backsheet can be conducted after tempering of the glass or before the aerodynamic heating. The thickness of the metal layer is not particularly limited, and typically, 100 nm to 300 nm would be suitable.

Moreover, although the solar backsheet in the solar module structure of the present invention has a reflecting layer, light still can penetrate through the reflecting layer and reach the surface of the glass substrate if the reflecting layer is thin. To enhance the reflection, the surface of the glass substrate at the same side as the reflecting layer in the solar backsheet of the present invention can be texturized to ensure that the light turns upward by scattering. Texturization can be done by conventional means including, but not limited to, sandblasting, embossing, engraving and laser engraving.

### First Polymeric Layer

The first polymeric layer of the present invention has two main functions: one is to secure the solar photovoltaic components and provide physical protection thereto, such as shock resistance and moisture resistance, and the other is to convert the light with a short wavelength into the light with a longer wavelength by the phosphors therein, so that the light can be efficiently used by the photovoltaic cell layer. The first polymeric layer can be made by blending any suitable encapsulating material that is known to the art with suitable phosphors, or coating the encapsulating material with phosphors.

Currently, EVA is the most extensively used encapsulating material for a solar panel. EVA is a thermosetting resin, has properties such as high light transmission, heat resistance, low-temperature resistance, moisture resistance, and weather proofing after curing, has good adherence with metal, glass and plastic, and also has certain elasticity, shock resistance and heat conductivity, and therefore is an ideal solar cell encapsulating material. The refractive index of EVA is 1.4 to 1.5, normally about 1.48.

The first polymeric layer according to the present invention can be made of other materials such as polyvinyl butyral (PVB), silica gel and thin-film ionomers (for example, DuPont PV5400).

When the photovoltaic cell layer is monocrystalline silicon or polycrystalline silicon, the phosphors incorporated in the first polymeric layer should have peak absorbance of 300 nm to 400 nm and peak emission of 450 nm to 500 nm to convert the light of short wavelength which is difficult to be absorbed by the monocrystalline or polycrystalline silicon into the light of longer wavelength.

Suitable phosphors can be inorganic phosphors, such as YAG or TAG in which Bi⁺³ or Tb⁺³ is added. Organic phosphors can be used, too. In addition to organic phosphors known to the art, the following novel organic phosphors can be used for achieving better efficiency:

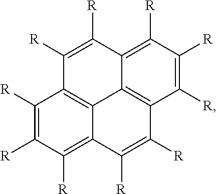

wherein two R of a symmetric pair are G1 and G2, respectively, and each of the remaining R is independently hydrogen, halogen or an aliphatic group which may be (but not limited to) C₁-C₆ alkyl, C₂-C₈ alkenyl, C₂-C₈ alkynyl, C₁-C₆ alkoxy, C₃-C₈ aliphatic cyclic group or C₃-C₈ heterocyclic group having at least one heteroatom of O, N or S, the aforementioned alkyl, alkenyl, alkynyl, alkoxy, aliphatic cyclic group or heterocyclic group being substituted by one or more aliphatic group or not substituted;

### G1 is:

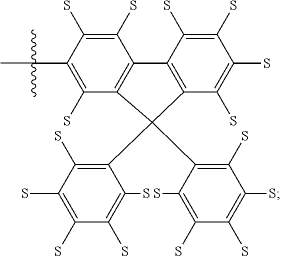

### G2 is

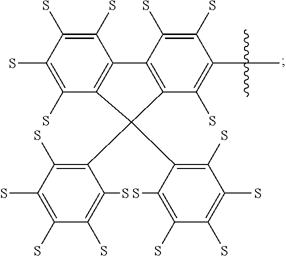 [SMILES: *c1c(S)c(S)c2c(c1S)C(c1c(S)c(S)c(S)c(S)c1S)(c1c(S)c(S)c(S)c(S)c1S)c1c(S)c(S)c(S)c(S)c1-2]

and
each S is independently hydrogen, halogen or an aliphatic group which may be (but not limited to) C₁-C₆ alkyl, C₂-C₈ alkenyl, C₂-C₈ alkynyl, C₁-C₆ alkoxy, C₃-C₈ aliphatic cyclic group or C₃-C₈ heterocyclic group having at least one heteroatom of O, N or S, the aforementioned alkyl, alkenyl, alkynyl, alkoxy, aliphatic cyclic group or heterocyclic group being substituted by one or more aliphatic group or not substituted, and any two S close to each other together with the carbon atoms to which they are attached to may form an aliphatic or hetero ring.

More preferred phosphors according to the present invention are:

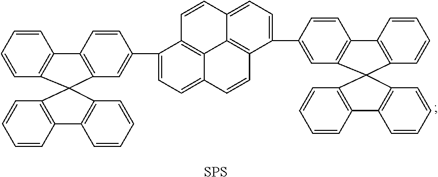 [SMILES: c1ccc2c(c1)-c1ccccc1C21c2ccccc2-c2ccc(-c3ccc4ccc5c(-c6ccc7c(c6)C6(c8ccccc8-c8ccccc86)c6ccccc6-7)ccc6ccc3c4c65)cc21 ; "SPS"]

(molecular formula: C₆₆H₃₈; Actual M.W: 830.297)

or

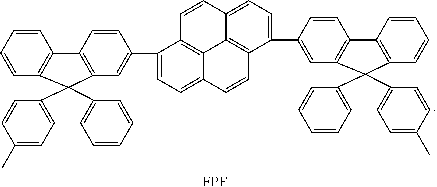 [SMILES: Cc1ccc(C2(c3ccccc3)c3ccccc3-c3ccc(-c4ccc5ccc6c(-c7ccc8c(c7)C(c7ccccc7)(c7ccc(C)cc7)c7ccccc7-8)ccc7ccc4c5c76)cc32)cc1 ; "FPF"]

(molecular formula: C₆₈H₄₆; Actual M.W: 862.360).

Preferably, the phosphors according to the present invention are particles or powders having a particle size of 10 nm to 2000 nm in average. The phosphors can be blended in the first polymeric layer or coated on the top or bottom surface of the first polymeric layer. Preferably, the phosphors are blended in the first polymeric layer.

### Photovoltaic Cell Layer

The photovoltaic cell layer according to the present invention is preferably a monocrystalline silicon or polycrystalline silicon solar cell layer, while other conventional materials, such as potassium arsonium, amorphous silicon, cadmium telluride, copper indium selenide, copper indium gallium selenide or a light-sensitized dye, can be used, too. When a material other than a monocrystalline silicon or a polycrystalline silicon is used as the photovoltaic cell layer, suitable phosphors should be chosen to convert the wavelength of the light difficult to be absorbed by the material to that can be absorbed more easily.

In order to effectively use the light converted by the phosphors in the first polymeric layer, a double-sided photovoltaic cell layer is required in the present invention, so that photoelectric conversion can be performed at the upper and lower sides of the photovoltaic cell layer. Double-sided photovoltaic cells are commercially available, such as the HIT series double-sided solar cell layer manufactured by SANYO, Japan.

### Second Polymeric Layer

The second polymeric layer of the present invention is also an encapsulating layer and can be made of any conventional encapsulating material such as EVA, polyvinyl butyral (PVB), silica gel and thin-film ionomers as mentioned above. Similar to the first polymeric layer, phosphors can be blended in or coated on the second polymeric layer. However, since the second polymeric layer is above the photovoltaic cell layer, most of the converted light will be scattered away from the light-incident surface, so the efficiency increased is very limited.

### Solar Cover Plate

The solar cover plate in the present invention is not particularly limited. Normally, transparent glass can be used, and it provides sufficient transparency and mechanical properties such as compressive strength, tensile strength and hardness, and can block moisture from entering the interior of the solar module. Preferably, the solar cover plate of the present invention is a tempered glass having a thickness of no more than 2 mm. The preparation and process requirements are discussed above in the section regarding the solar backsheet.

### EXAMPLES

Preparations of the preferred phosphors in the present invention, namely, SPS and FPS, and the comparative examples, SAS and FAF, are discussed below.

Preferred examples of phosphors SPS and FPF and comparative examples SAS and FAF can be prepared via the following schemes. The detailed reaction steps are described in Examples 1 and 2 and Comparative examples 1 and 2.

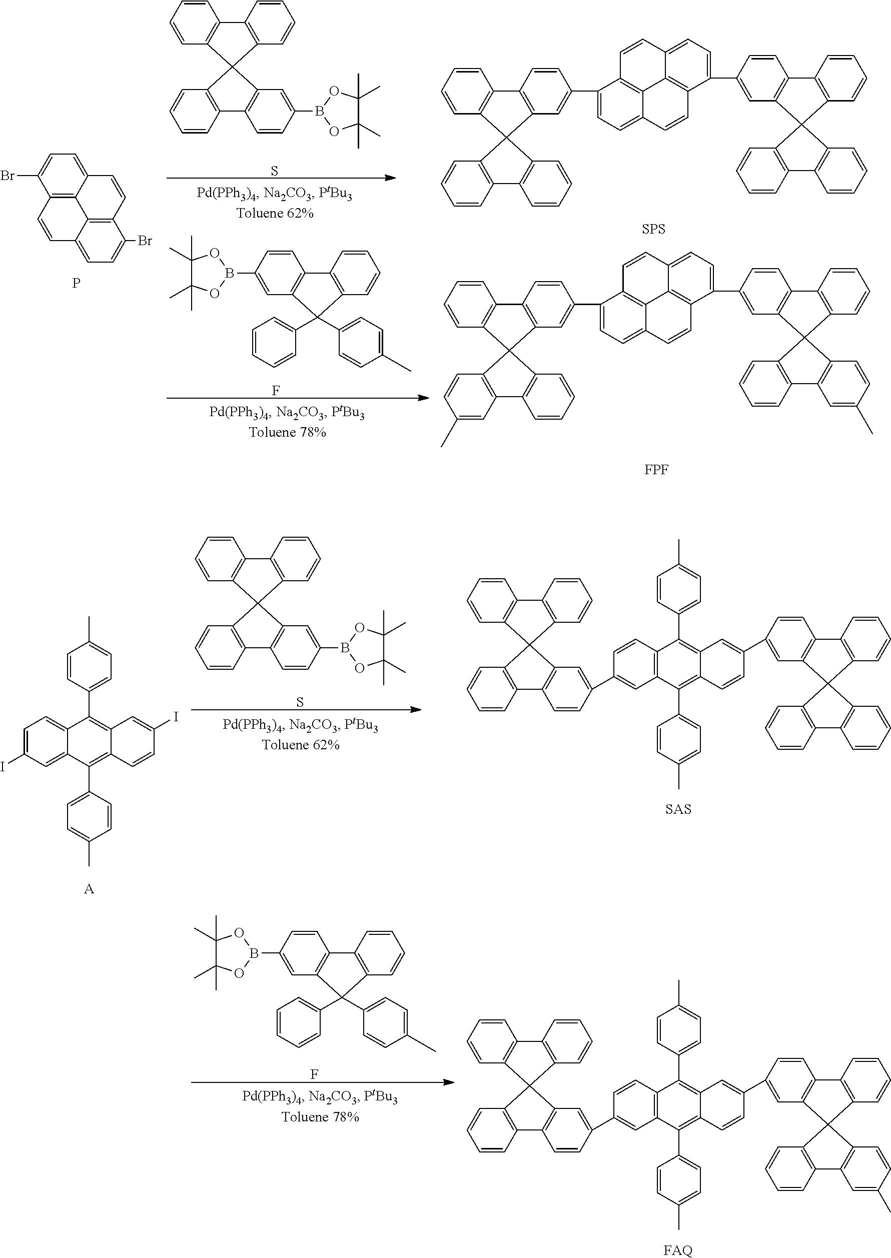

### Example 1

### Preparation of SPS

Adding to two-neck flask (250 mL) installed with a condenser Compound S (2.11 g, 4.8 mmol), Compound P (0.72 g, 2 mmol), Pd(PPh₃)₄ (0.24 g, 0.2 mmol) and a stir bar. Evacuating the flask and then filling it with argon. Gradually adding to the flask water-free toluene (100 ml), 0.05M P^{t}Bu₃ (4 mL, 2 mmol) and 2M K₂CO₃ aqueous solution (5.5 mL, 8 mmol). Refluxing, heating (120° C.) and stirring the mixture for three days. Washing the filtered residue with methanol, pure water, ethyl acetate and carbon dichloride in sequence until the residue becoming golden. Golden solid SPS (1.02 g, 62%) was obtained.

¹H NMR (CDCl₃, 400 MHz) δ 8.00 (d, J=2.4 Hz, 4H), 7.98 (t, J=8.0 Hz, 4H), 7.81˜7.77 (m, 8H), 7.62 (d, J=8.0 Hz, 2H), 7.41 (t, J=8.0 Hz, 2H), 7.34 (t, 4H), 7.14 (s, J=8.0 Hz, 6H), 6.97 (d, J=8.0 Hz, 2H), 6.87 (d, J=8.0 Hz, 4H), 6.78 (d, J=8.0 Hz, 2H); HRMS (m/z, FAB+); molecular formula: C66H38; actual molecular weight: 830.2965.

### Example 2

### Preparation of FPF

Adding to a two-neck flask (50 mL) installed with a condenser Compound F (0.55 g, 1.2 mmol), Compound P (0.18 g, 0.5 mmol), Pd(PPh₃)₄ (0.06 g, 0.05 mmol) and a stir bar. Evacuating the flask and filling it with argon. Gradually adding to the flask water-free toluene (20 mL), 0.05M P^{t}Bu₃ (1 mL, 0.1 mmol) and 2M K₂CO₃ aqueous solution (1.375 mL, 2 mmol). Refluxing, heating (120° C.) and stirring the mixture for three days. Extracting the mixture by chloroform (CHCl₃) and water. Collecting the organic phase, removing water by using anhydrous magnesium sulfate and removing solvent using a rotary evaporator. Chromatography in capillary gel column with chloroform/n-hexane/toluene in a ratio of 1/8/1 as elution was performed to obtain a golden liquid. After drying the liquid with a rotary evaporator, golden solid FPF (0.34 g, 78%) was obtained.

¹H NMR (CD₂Cl₂, 400 MHz) δ 8.15 (d, J=4.0 Hz, 4H), 7.98˜7.95 (m, 6H), 7.88 (d, J=8.0 Hz, 2H), 7.72 (s, 2H), 7.66 (t, J=4.0 Hz, 2H), 7.45˜7.41 (m, 4H), 7.35˜7.18 (m, 18H), 7.06 (d, J=8.0 Hz, 4H), 2.12 (s, 6H); ¹³C NMR (CD₂Cl₃, 100 MHz) δ 152.2, 152.1, 146.6, 143.4, 141.1, 140.4, 139.9, 138.4, 137.1, 130.9, 130.6, 129.5, 129.3, 129.0, 128.8, 128.7, 128.6, 128.5, 128.4, 128.2, 127.9, 127.0, 127.3, 126.8, 125.7, 125.0, 121.0, 120.8, 65.9, 21.2; HRMS (m/z, FAB+); molecular formula C67H46; actual molecular weight 862.3598.

### Comparative Example 1

### Preparation of SAS

Adding to a two-neck flask (50 mL) installed with a condenser Compound S (0.53 g, 1.2 mmol), Compound A (0.305 g, 0.5 mmol), Pd(PPh₃)₄ (0.06 g, 0.5 mmol) and a stir bar. Evacuating the flask and then filling it with argon. Gradually adding to the flask water-free toluene (30 mL), 0.05M P^{t}Bu₃ (1 mL, 0.1 mmol) and 2M K₂CO₃ aqueous solution (1.375 mL, 2 mmol). Refluxing, heating (120° C.) and stirring the mixture for three days. Washing the filtered residue with methanol, pure water, ethyl acetate and carbon dichloride in sequence until the residue becoming golden. Golden solid SAS (0.34 g, 68%) was obtained.

¹H NMR (CDCl₃, 400 MHz) δ 7.83 (d, J=8.0 Hz, 8H), 7.73 (s, 2H), 7.62 (d, J=8.0 Hz, 2H), 7.52 (d, J=8.0 Hz, 2H), 7.36˜7.31 (m, 14H), 7.11˜7.05 (m, 6H), 6.84 (s, 2H), 6.73 (t, J=8.0 Hz, 6H), 2.51 (s, 6H); FIRMS (m/z, FAB+); molecular formula: C78H50; actual molecular weight: 986.3932.

### Comparative Example 2

### Preparation of FAF

Adding to a two-neck flask (50 mL) installed with a condenser Compound F (0.55 g, 1.2 mmol), Compound A (0.305 g, 0.5 mmol), Pd(PPh₃)₄ (0.06 g, 0.5 mmol) and a stir bar. Evacuating the flask and then filling it with argon. Gradually added water-free toluene (30 mL), 0.05M P^{t}Bu₃ (1 mL, 0.1 mmol) and 2M K₂CO₃ aqueous solution (1.375 mL, 2 mmol). Reflexing, heating (120° C.) and stirring the mixture for three days and then extracting the mixture by chloroform (CHCl₃) and water. Collecting the organic phase and removing the organic solvent by using a rotary evaporator. Chromatography in gel column with n-hexane/toluene/chloroform in a ratio of 20/5/1 as elution was performed to obtain a golden liquid. After drying the liquid with a rotary evaporator, golden solid FAF (0.37 g, 72%) was obtained.

¹H NMR (CDCl₃, 400 MHz) δ 7.88 (s, 2H), 7.75 (t, J=8.0 Hz, 6H), 7.59 (s, 2H), 7.56˜7.53 (m, 4H), 7.41˜7.33 (m, 16H), 7.18 (s, 8H), 7.08 (d, J=8.0 Hz, 4H), 7.00 (d, J=8.0 Hz, 4H), 2.57 (s, 6H), 2.29 (s, 6H); ¹³C NMR (CDCl₃, 100 MHz) δ 151.8, 151.3, 145.9, 142.7, 141.0, 140.3, 139.6, 139.5, 137.8, 136.2, 129.7, 129.0, 128.9, 128.1, 128.0, 127.7, 127.4, 127.3, 126.7, 126.5, 126.2, 125.2, 123.9, 122.4, 120.3, 120.2, 84.0, 65.1, 21.4, 20.9; HRMS (m/z, FAB+); molecular formula: C80H58 1018.4539, actual molecular weight: 1018.4550.

### Example 3

### Analysis on Optical Properties

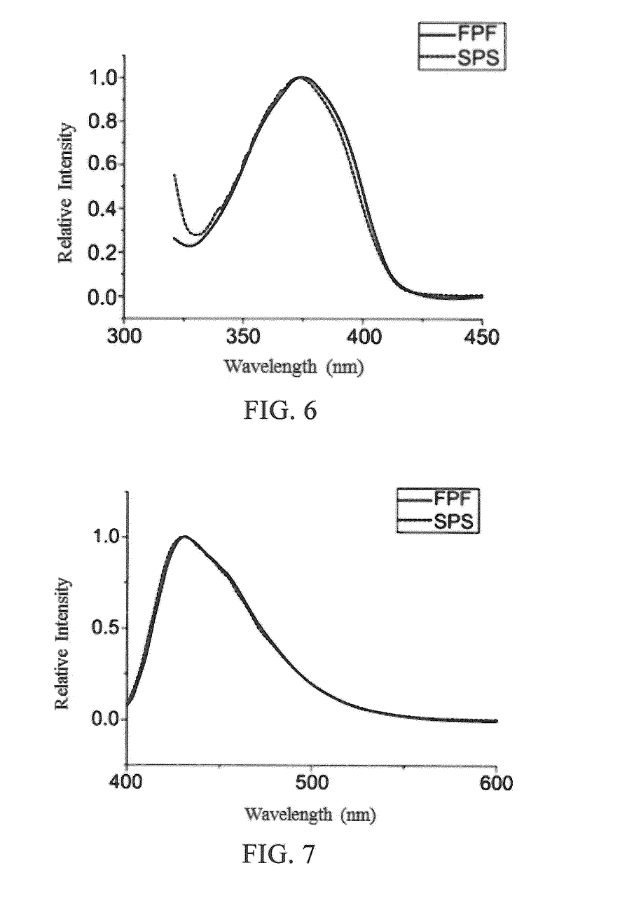

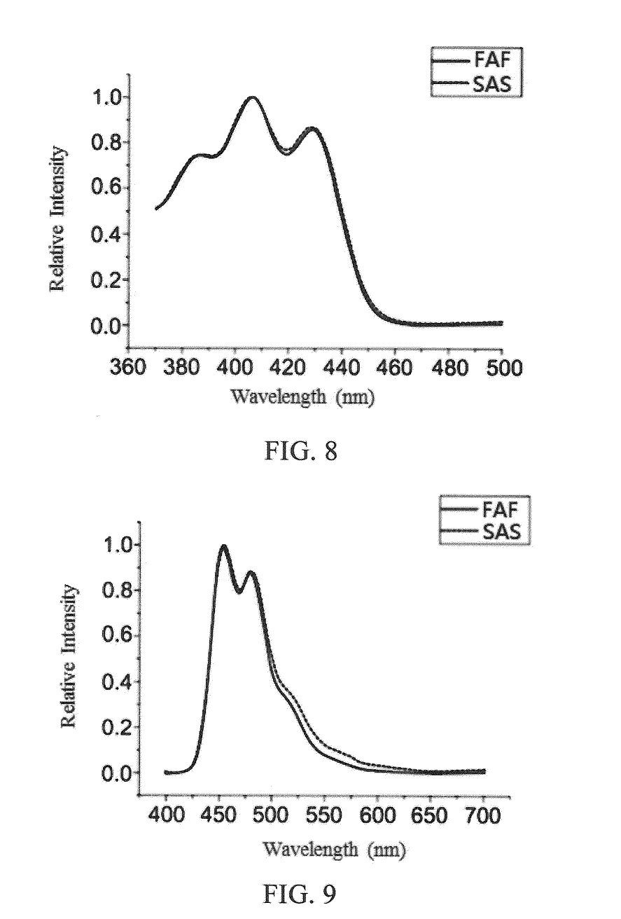

Standard solutions separately containing SPS, SAS, FPF and FAF were measured with a spectrophotometer. The optical properties measured for each sample are shown in the following table and in FIGS. 6 to 9.

| | absorbance | | emission | | Quantum yield |
|---|---|---|---|---|---|
| SPS | 373.5 | nm | 429.6 | nm | 99% |
| SAS | 387.5/405.5/428.5 | nm | 454.4/480 | nm | 59% |
| FPF | 375 | nm | 430.6 | nm | 99% |
| FAF | 386.5/406/429 | nm | 453.8/478.6 | nm | 58% |

From the data in the above table, it can be known that the preferred phosphors SPS and FPF, which are similar to SAS and FAF illustrated in Comparative Examples in terms of structure, result in superior quantum yields. By using SPS and FPF in the solar module of the present invention, the overall conversion efficiency can be significantly improved.

It should be understood that the foregoing description as well as the accompanying drawings are for illustrating the present invention and should not be interpreted as limitations to the scope of the present invention. The scope of the invention should only be limited by the appended claims, and any modification or change that can be easily implemented by a person of ordinary skill in the art should be considered to be within the scope of the specification and claims.

What is claimed is:

1. A solar module structure comprising in sequence:
a solar backsheet that can reflect light;
a first polymeric layer comprising phosphors;
a double-sided photovoltaic cell layer;
a second polymeric layer;
a cover plate made of tempered glass;
wherein the phosphors have peak absorbance of 300 nm to 400 nm and peak emission of 450 nm to 500 nm.

2. The solar module structure of claim 1, wherein the double-sided photovoltaic cell layer comprises a double-sided monocrystalline or polycrystalline silicon photovoltaic cell layer.

3. The solar module structure of claim 1, wherein the phosphors are organic phosphors.

4. The solar module structure of claim 3, wherein the phosphors are selected from: 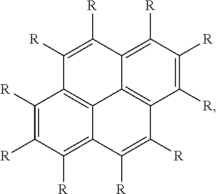
wherein two R of a symmetric pair are G1 and G2, respectively, and each of the remaining R is independently hydrogen, halogen or an aliphatic group which is substituted or unsubstituted;
G1 is 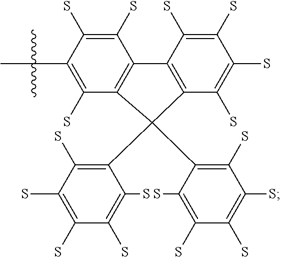
G2 is 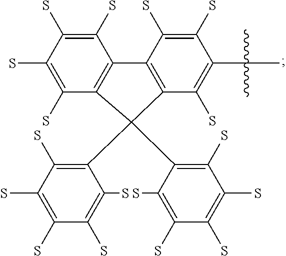 [SMILES: *c1c(S)c(S)c2c(c1S)C(c1c(S)c(S)c(S)c(S)c1S)(c1c(S)c(S)c(S)c(S)c1S)c1c(S)c(S)c(S)c(S)c1-2]
and
each S is independently hydrogen, halogen or an aliphatic group, and any two S close to each other together with the carbon atoms to which they are attached to may form an aliphatic or hetero ring.

5. The solar module structure of claim 4, wherein the phosphors are selected from the group consisting of

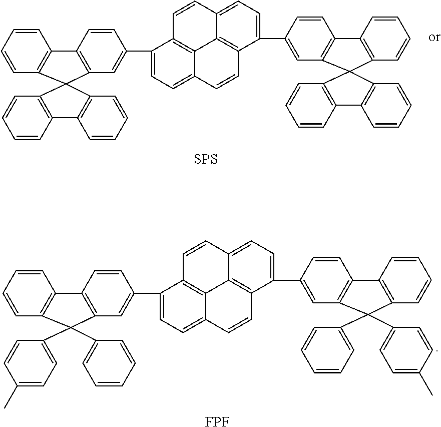

6. The solar module structure of claim 1, wherein the phosphors have an average particle size of 10 nm to 2000 nm.

7. The solar module structure of claim 1, wherein the backsheet is a tempered glass backsheet with a metal reflecting layer coated thereon.

8. The solar module structure of claim 7, wherein the backsheet and the tempered glass cover plate each has a thickness of no more than 2 mm.

9. The solar module structure of claim 7, wherein the metal reflecting layer is selected from the group consisting of silver, aluminum, gold, chromium and an alloy thereof.

10. The solar module structure of claim 1, wherein the backsheet is a polymeric layer in white color.

11. The solar module structure of claim 1, wherein the first polymeric layer and the second polymeric layer comprise a material selected from the group consisting of ethylene vinyl acetate (EVA), polyvinyl butyral (PVB), silica gel and thin-film ionomers.
